(19) United States
(12) Patent Application Publication
(10) Pub. No.: US 2008/0274580 A1
(43) Pub. Date: Nov. 6, 2008

(54) METHOD FOR MANUFACTURING IMAGE SENSOR

(76) Inventor: Chung-Kyung Jung, Anyang-si (KR)

Correspondence Address: SHERR & VAUGHN, PLLC, 620 HERNDON PARKWAY, SUITE 200, HERNDON, VA, 20170, US

(21) Appl. No.: 12/111,995

(22) Filed: Apr. 30, 2008

(30) Foreign Application Priority Data
May 3, 2007 (KR) 10-2007-0042908

(51) Int. Cl. H01L 31/0232

(52) U.S. Cl. 438/70; 257/E31.127

(57) ABSTRACT

A method for manufacturing an image sensor including forming a metal line layer on a semiconductor substrate, and then forming color filters on the metal line layer, and then forming seed microlenses spaced apart on the color filters, and then cleaning the surface of the seed microlenses, and then forming a gapless microlenses on the color filters by depositing an inorganic layer on the seed microlenses and in spaces therebetween. A gapless microlens can prevent crosstalk and noise and enhance the image quality of the image sensor. Forming the microlens of thin inorganic layer can prevent cracking due to physical impacts. The adhesive force can be enhanced between the first and second organic films of the microlens by performing cleaning processes, which in turn, enhances the refractive index and light transmittance for incident light.

The present application claims priority under 35 U.S.C. 119 and 35 U.S.C. 365 to Korean Patent Application No. 10-2007-0042908 (filed on May 3, 2007), which is hereby incorporated by reference in its entirety.

### BACKGROUND

An image sensor is a semiconductor device for converting an optical image into an electrical signal. Image sensors may be roughly classified into a charge coupled device (CCD) and a complementary metal oxide semiconductor (CMOS) image sensor (CIS).

The CIS may include a plurality of photodiodes and MOS transistors in a unit pixel for sequentially detecting electrical signals of respective unit pixels in a switching manner to realize an image.

A microlens may be formed on and/or over a color filter to enhance light sensitivity of the CIS. The microlens may be formed in a semicircular shape by sequentially performing an exposure process, a development process, and a reflow process on and/or over a photosensitive organic material.

### SUMMARY

Embodiments relate to a method for manufacturing an image sensor including a plurality of microlenses composed of an inorganic material.

Embodiments relate to a method for manufacturing an image sensor that can include at least one of the following steps: forming a metal line layer on a semiconductor substrate; and then forming color filters on the metal line layer; and then forming seed microlenses spaced apart on the color filters; and then cleaning the surface of the seed microlenses; and then forming a gapless microlenses on the color filters by depositing an inorganic layer on the seed microlenses and in spaces therebetween.

Embodiments relate to a method for manufacturing an image sensor that can include at least one of the following steps: providing a semiconductor substrate having a plurality of unit pixels; and then forming a light detecting portion for each unit pixel; and then forming an interlayer dielectric layer including a plurality of metal lines each electrically connected to a respective light detecting portion; and then forming a color filter array on the interlayer dielectric layer; and then forming a seed microlens array formed spaced apart directly on the color filter array, wherein the seed microlens array includes a seed microlens for each unit pixel; and then performing cleaning processes at least on the surface of the seed microlens array; and then forming a microlens directly on the color filter array by depositing a first inorganic layer on the seed microlenses and filling spaces between adjacent seed microlenses.

Embodiments relate to a method for manufacturing an image sensor that can include at least one of the following steps: forming an interlayer dielectric layer including a plurality of metal lines directly on a substrate; and then forming a plurality of color filters directly on the interlayer dielectric layer; and then forming a plurality of seed microlenses spaced apart directly on the color filters, wherein the seed microlenses are composed of a first inorganic layer; and then sequentially performing cleaning processes on the surface of the seed microlenses; and then forming a microlens having directly on the color filter array by depositing a second inorganic layer on the seed microlenses and filling spaces between adjacent seed microlenses, wherein the microlens has a continuous surface shape.

### DRAWINGS

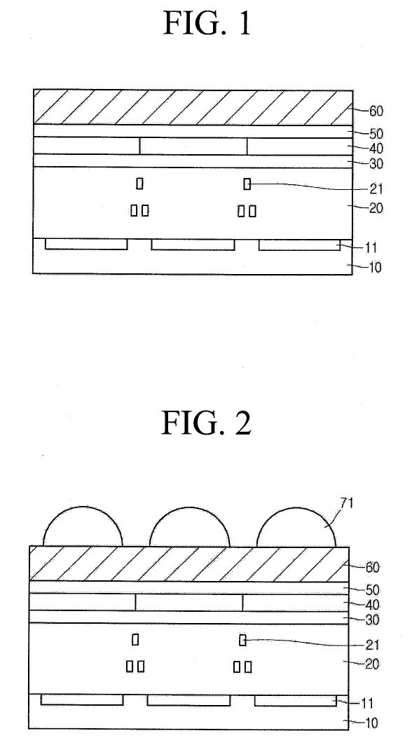

Example FIGS. 1 to 5 are views illustrating a manufacturing process of an image sensor, in accordance with embodiments.

### DESCRIPTION

As illustrated in example FIG. 1, semiconductor substrate 10 can include a plurality of light detecting portions 11 formed for each unit pixel of semiconductor substrate 10. A device isolation layer defining an active region and a field region can be formed on and/or over semiconductor substrate 10. Light detecting portion 11 can include a photodiode receiving light to generate a photo charge, and a CMOS circuit connected to the photodiode for converting the generated photo charge into an electrical signal.

After related devices including the device isolation layer and light detecting portion 11 are formed, interlayer dielectric 20 can be formed on and/or over semiconductor substrate 10. Interlayer dielectric 20 can include a plurality of metal lines 21 and also be formed having a multi-layer structure including a plurality of layers. Each metal line 21 can have an intentional layout not to screen light incident to the photodiode. Metal line 21 can be electrically connected to light detecting portion 11.

Passivation layer 30 can be formed on and/or over interlayer dielectric 20 including metal lines 21. Passivation layer 30 can be provided for protecting a device from moisture or starches. Passivation layer 30 can be composed of a dielectric material. Passivation layer 30 can be composed of one of a silicon oxide (SiO₂) layer, a silicon nitride (SiN) layer, and a silicon oxide nitride (SiON) layer. Passivation layer 30 can have a multilayer structure in which at least one of the layers is stacked. For example, passivation layer 30 can have a stacked structure including a tetraethyl-ortho-silicate (TEOS) layer having a thickness of between 1,000-5,000 Å and a nitride layer having a thickness of between 1,000-10,000 Å.

In accordance with embodiments, use of passivation layer 30 can be omitted, and a plurality of color filters 40 can be formed directly on and/or over interlayer dielectric 20 during a subsequent process. This configuration influences the entire height of the image sensor, so that a thinner image sensor can be provided. Also, a cost reduction effect due to reduction in the number of processes can be provided.

Alternatively, color filters 40 can be formed directly on and/or over passivation layer 30 and include three color filters 40 for realizing a color image. Examples of a material that can be used for color filters 40 include a dyed photoresist. One color filter 40 can be formed on and/or over each unit pixel to separate color from incident light. Color filters 40 can represent different colors, respectively, such as red, green, and blue. Adjacent color filters 40 can slightly overlap each other to have a height difference. To complement this height difference, planarization layer 50 can be formed directly on and/or over color filters 40. Microlenses to be formed in a subsequent process can be formed on and/or over a planarized surface. Therefore, planarization layer 50 can be formed on and/or over color filters 40 to remove the height difference caused by color filters 40. Of course, planarization layer 50 can be omitted.

Inorganic layer 60 can then be formed on and/or over color filters 40 to form an array of seed microlenses. Inorganic layer 60 can be formed of an oxide layer, a nitride layer, and a nitride oxide layer. For example, inorganic layer 60 can be formed by performing chemical vapor deposition (CVD), physical vapor deposition (PVD), or plasma enhanced CVD (PECVD) on and/or over an oxide layer at a low temperature of about 50-250° C. Inorganic layer 60 can be formed having a thickness of about 2,000-20,000 Å.

As illustrated in example FIG. 2, microlens mask 71 in the array can be formed for each unit pixel on and/or over inorganic layer 60. Each microlens mask 71 can be formed in a semispherical or dome shape by coating inorganic layer 60 with an organic photoresist layer, patterning the organic photoresist layer using a lithography process, and performing a reflow process. Microlens mask 71 corresponding to one unit pixel can be separated from microlens mask 71 corresponding to an adjacent unit pixel.

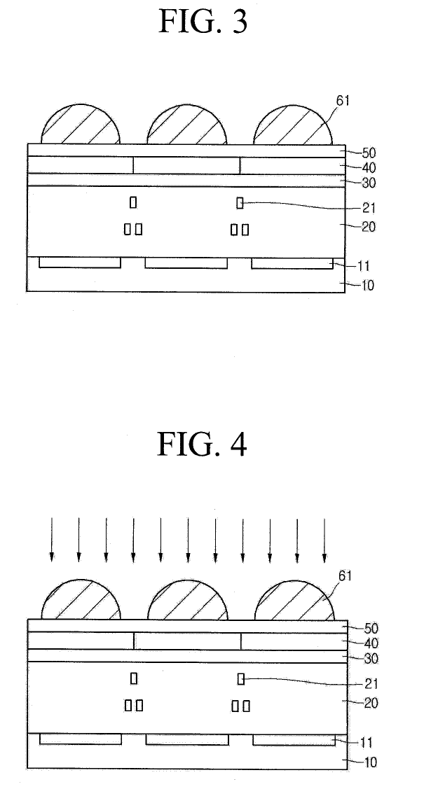

As illustrated in example FIG. 3, an array of seed microlenses 61 can then be formed on and/or over color filters 40. Seed microlenses 61 can be formed by performing a blanket etching on and/or over inorganic layer 60 using microlens masks 71 as an etch mask. The blanket etching of inorganic layer 60 can be performed at an etching ratio of 1:1 between inorganic layer 60 and microlens masks 71. Therefore, the etching of inorganic layer 60 for forming seed microlenses 61 can be performed until the organic photoresist layer is completely etched, so that seed microlens 61 can be formed spaced apart from an adjacent microlens 61. Meaning, each seed microlens 61 can be separated from each other for each unit pixel in order to prevent the occurrence of a merge and bridge phenomenon of microlenses. Accordingly, seed microlenses 61 including a low temperature oxide layer can be formed spaced apart on and/or over color filters 40. Accordingly, the sensitivity of an image sensor is not reduced.

As illustrated in example FIG. 4, a surface cleaning process for the array of seed microlenses 61 can then be performed. The surface cleaning process for seed microlenses 61 is performed to remove undesirable particles such as residuals of the organic photoresist layer left on and/or over seed microlenses 61 during formation of seed microlenses 61. Such particles and/or residual materials of the photoresist layer can reduce the adhesive force of a subsequent inorganic layer deposited on and/or over microlenses 61, and may act as a defect source of an image. The surface cleaning process for seed microlenses 61 is performed using a basic solution. While the cleaning process is performed, an oxide layer forming seed microlenses 61 should not be damaged. Therefore, the cleaning process is performed within about 10-200 seconds using a basic solvent. Particularly, the cleaning process can be performed within about 30-60 seconds using a NH₄F solution-based basic solvent. By doing so, the surface damage of seed microlenses 61 is prevented and simultaneously the residuals of the photoresist layer can be easily removed. Also, since the surface damage of seed microlenses 61 is prevented, the refractive index and reflectivity of the microlenses can be enhanced, and the adhesive force for a subsequent inorganic thin layer formed over seed microlenses 61 can be enhanced. Additionally, after conducting an initial cleaning of seed microlenses 61 using a basic solution, a second cleaning process can be performed using deionized (DI) water. After performing the second cleaning process, a drying process can be performed.

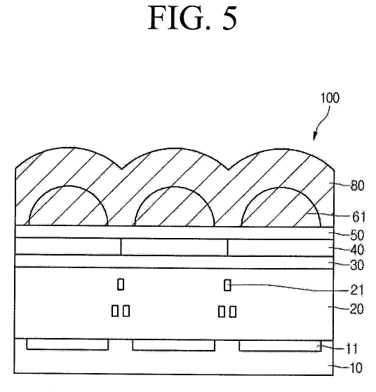

As illustrated in example FIG. 5, thin inorganic layer 80 can then be deposited on and/or over seed microlenses 61 and in spaced in between adjacent microlenses 61 to form gapless microlenses 100. Thin inorganic layer 80 can be deposited on and/or over the upper surface of seed microlenses 61 so that microlenses 100 formed of the inorganic thin layer 80 is formed having a gapless shape. Since seed microlens 61 are formed spaced apart, microlenses 100 formed by depositing thin inorganic layer 80 on and/or over seed microlenses 61 and in spaces therebetween can have a structure in which gaps between adjacent microlenses are removed. Therefore, microlenses 100 including the array of seed microlenses 61 and inorganic thin layer 80 can have a continuous dome shape, so that gapless microlenses can be formed.

Thin inorganic layer 80 can be formed of the same material as that of seed microlenses 61. For example, thin inorganic layer 80 can be formed by depositing an oxide layer having a thickness of about 500-20,000 Å at a temperature of about 50-250° C. Particularly, thin inorganic layer 80 can be deposited until the gaps between seed microlenses 61 are removed. Therefore, since thin inorganic layer 80 can be deposited to a thin thickness on and/or over seed microlenses 61, a distal lateral end of microlens 100 continuously contacts adjacent microlenses 100. With this structure, an interval between microlenses 100 is reduced to a zero gap level, so that crosstalk and a noise can be prevented and thus the image quality of the image sensor can be improved. Also, since microlenses 100 including seed microlenses 61 and thin inorganic layer 80 can be formed of an inorganic material, cracks due to physical impacts can be prevented.

After seed microlenses 61 are formed, the residuals of the photoresist layer can be removed through cleaning processes to enhance the adhesive force between seed microlenses 61 and thin inorganic layer 80.

By removing residuals such as photoresist particles, thin inorganic layer 80 can be deposited on and/or over the surface of seed microlenses 61, to enhance the refractive index and light transmittance for incident light.

Since seed microlenses 61 are cleaned using the basic solution, surface damage to microlenses 100 can be prevented.

A method for manufacturing an image sensor in accordance to embodiments can form microlenses using an inorganic material to prevent damage to the microlenses (e.g., crack) by either particles and/or physical impact, so that the quality of an image sensor can be enhanced.

The microlenses can be formed in a double layer including a first inorganic layer and a second inorganic layer to form gapless microlenses, so that a light detection ratio of an image sensor can be enhanced.

After the first inorganic layer is formed, surface cleaning processes can be performed to enhance the adhesive force when a second inorganic layer is subsequently formed. The refractive index and light transmittance of the microlenses can also be enhanced.

Organic residual materials, particles and/or debris can be removed through a surface cleaning process for the first inorganic layer to prevent occurrence of a black point defect to thereby enhance the yield of an image sensor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing an image sensor, the method comprising:
forming a metal line layer on a semiconductor substrate; and then
forming color filters on the metal line layer; and then
forming seed microlenses spaced apart on the color filters; and then
cleaning the surface of the seed microlenses; and then
forming a gapless microlenses on the color filters by depositing an inorganic layer on the seed microlenses and in spaces therebetween.

2. The method of claim 1, wherein the seed microlenses are cleaned using at least one of a NH₄F solution and deionized water.

3. The method of claim 2, wherein the cleaning of the surfaces of the seed microlenses is performed in about 10-200 seconds.

4. The method of claim 1, wherein forming the array of seed microlenses comprises:
forming a second inorganic layer on the metal line layer; and then
forming lens masks spaced apart on the second inorganic layer; and then
etching the second inorganic layer using the lens masks as etch masks.

5. The method of claim 4, wherein the lens masks are composed of a photoresist material.

6. The method of claim 4, wherein the second inorganic layer and the lens masks are etched at an etching ratio of 1:1.

7. The method of claim 1, wherein the seed microlenses each comprise an oxide layer, a nitride layer and an oxide nitride layer.

8. The method of claim 1, wherein the inorganic thin layer comprises an oxide layer, a nitride layer and an oxide nitride layer.

9. The method of claim 1, wherein the seed microlenses and the inorganic layer are deposited at a temperature of between 100-200° C.

10. The method of claim 1, further comprising forming a passivation layer on the metal line layer before forming the color filters.

11. The method of claim 1, further comprising forming a planarization layer on the color filters before forming the second inorganic film.

12. A method comprising:
providing a semiconductor substrate having a plurality of unit pixels; and then
forming a light detecting portion for each unit pixel; and then
forming an interlayer dielectric layer including a plurality of metal lines each electrically connected to a respective light detecting portion; and then
forming a color filter array on the interlayer dielectric layer; and then
forming a seed microlens array formed spaced apart directly on the color filter array, wherein the seed microlens array includes a seed microlens for each unit pixel; and then
performing cleaning processes at least on the surface of the seed microlens array; and then
forming a microlens directly on the color filter array by depositing a first inorganic layer on the seed microlenses and filling spaces between adjacent seed microlenses.

13. The method of claim 12, wherein forming the seed microlens array comprises:
forming a second inorganic layer directly on the color filter array; and then
forming a microlens mask array directly on the second inorganic layer; and then
performing a blanket etching on the second inorganic layer using the microlens mask array as an etch mask.

14. The method of claim 13, wherein the first inorganic layer has a thickness of between about 500-20,000 Å and the second inorganic layer has a thickness of between about 2,000-20,000 Å.

15. The method of claim 13, wherein the first inorganic layer and the second inorganic layer each comprise an oxide layer, a nitride layer, and a nitride oxide layer.

16. The method of claim 12, wherein the cleaning processes comprises:
performing a first cleaning process on the surface of the seed microlens array using a NH₄F solution; and then
performing a second cleaning process on the surface of the seed microlens array using deionized water; and then
drying the surface of the seed microlens array.

17. A method comprising:
forming an interlayer dielectric layer including a plurality of metal lines directly on a substrate; and then
forming a plurality of color filters directly on the interlayer dielectric layer; and then forming a plurality of seed microlenses spaced apart directly on the color filters, wherein the seed microlenses are composed of a first inorganic layer; and then
sequentially performing cleaning processes on the surface of the seed microlenses; and then
forming a microlens having directly on the color filter array by depositing a second inorganic layer on the seed microlenses and filling spaces between adjacent seed microlenses, wherein the microlens has a continuous surface shape.

18. The method of claim 17, wherein sequentially forming cleaning processes comprises:
performing a first cleaning process on the surface of the seed microlenses using a NH₄F solution; and then
performing a second cleaning process on the surface of the seed microlenses using deionized water.

19. The method of claim 18, wherein the first cleaning process is performed using a NH₄F solution and the second cleaning process is performed using deionized water.

20. The method of claim 19, further comprising drying the surface of the seed microlenses after performing the second cleaning process.
